(19) United States
(12) Patent Application Publication
(10) Pub. No.: US 2024/0420972 A1
(43) Pub. Date: Dec. 19, 2024

(54) SEMICONDUCTOR MOLDING APPARATUS AND COMPRESSION MOLDING METHOD USING THE SAME

(71) Applicant: SAMSUNG ELECTRONICS CO., LTD., Suwon-si (KR)

(72) Inventors: Taejun JEON, Suwon-si (KR); Yongkwan LEE, Suwon-si (KR); Gyuhyeong KIM, Suwon-si (KR); Seung Hwan KIM, Suwon-si (KR); Jongwan KIM, Suwon-si (KR); Junwoo PARK, Suwon-si (KR)

(21) Appl. No.: 18/402,567

(22) Filed: Jan. 2, 2024

(30) Foreign Application Priority Data
Jun. 13, 2023 (KR) 10-2023-0075713

(51) Int. Cl. H01L 21/67; H01L 21/56

(52) U.S. Cl. CPC H01L 21/67126; H01L 21/565

(57) ABSTRACT

Disclosed are semiconductor molding apparatuses and compression molding methods. The semiconductor molding apparatus comprises an upper mold capable of supporting a substrate, a lower mold that provides a first cavity capable of being filled with a resin, a guide member that provides a second cavity to be filled with the resin and vertically penetrates the lower mold, and a guide lift capable of driving the guide member to vertically move. The lower mold includes a base plate that extends in a horizontal direction and a sidewall member that upwardly extends from the base plate. The guide lift drives the guide member to vertically move such that a top surface of the guide member moves between a top surface of the base plate and a top surface of the sidewall member.

### CROSS-REFERENCE TO RELATED APPLICATION

This U.S. nonprovisional application claims priority under 35 U.S.C § 119 to Korean Patent Application No. 10-2023-0075713 filed on Jun. 13, 2023 in the Korean Intellectual Property Office, the disclosure of which is hereby incorporated by reference in its entirety.

### BACKGROUND

An encapsulation process is defined as a process where a semiconductor chip is surrounded by a specific material to protect against external environment. The encapsulation process includes a hermetic method in which a ceramic plate or a metal hood is attached to encapsulate or a molding method in which a plastic epoxy material is melted and cured to encapsulate.

An epoxy molding compound (EMC) is a kind of plastic used in a molding process. When the EMC is cooled after being melted at 150° C. or higher, the EMC and a printed circuit board (PCB), a lead frame, and a wafer are strongly bonded into a hard material.

### SUMMARY

The present disclosure relates to a semiconductor molding apparatus and a compression molding method using the same, and more particularly, to a semiconductor molding apparatus capable of increasing flowability of resin by utilizing a resin dispensing method using a guide member and a compression molding method using the same.

In general, in some aspects, the subject matter of the present disclosure is directed to a semiconductor molding apparatus capable of increasing flowability of resin in a joint-gap and a compression molding method using the same.

In general, in some aspects, the subject matter of the present disclosure is directed to a semiconductor molding apparatus capable of reducing flow asymmetry of resin between a joint-gap and a chip-top and a compression molding method using the same.

In general, in some aspects, the subject matter of the present disclosure is directed to a semiconductor molding apparatus capable of reducing the occurrence of void in a molding procedure and a compression molding method using the same.

In general, in some aspects, the subject matter of the present disclosure is directed to a semiconductor molding apparatus capable of reducing a flow length of resin and a compression molding method using the same.

The present disclosure is not limited to the aspects mentioned above, and other aspects which have not been mentioned above will be understood to those skilled in the art from the following description.

In general, aspects of the subject matter described in this specification can be embodied in a semiconductor molding apparatus including: an upper mold capable of supporting a substrate; a lower mold that provides a first cavity capable of being filled with a resin; a guide member that provides a second cavity to be filled with the resin and vertically penetrates the lower mold; and a guide lift capable of driving the guide member to vertically move. The lower mold may include: a base plate that extends in a horizontal direction; and a sidewall member that upwardly extends from the base plate. The guide lift may drive the guide member to vertically move such that a top surface of the guide member moves between a top surface of the base plate and a top surface of the sidewall member.

In general, in some aspects of the present disclosure can be embodied in a semiconductor molding apparatus including: an upper mold capable of supporting a substrate; a lower mold that provides a first cavity capable of being filled with a resin; a guide member that provides a second cavity capable of storing the resin and capable of being combined with the lower mold; and a guide lift capable of driving the guide member to vertically move. The lower mold may include: a base plate that has a top surface defining the first cavity; and a sidewall member that upwardly extends from the base plate and has an inner lateral surface defining the first cavity. The guide lift may allow a top surface of the guide member to move between the top surface of the base plate and a top surface of the sidewall member.

In general, aspects of the present disclosure can be embodied in a compression molding method including: introducing a resin into a semiconductor molding apparatus; and performing a semiconductor molding process. The semiconductor molding apparatus may include: an upper mold capable of supporting a substrate; a lower mold that provides a first cavity capable of being filled with the resin; a lower mold lift capable of driving the lower mold to vertically move; and a guide member that provides a second cavity capable of storing the resin when the resin is introduced into the semiconductor molding apparatus, the guide member vertically penetrating the lower mold. The step of introducing the resin into the semiconductor molding apparatus may include introducing the resin to the second cavity in a state where the guide member is positioned in the first cavity. The step of performing the semiconductor molding process may include: allowing the lower mold and the upper mold to approach each other to close the first cavity in a state where the resin is introduced into the second cavity; and allowing the guide member to move downwardly to cause a top surface of the guide member to be disposed below the first cavity.

### BRIEF DESCRIPTION OF THE DRAWINGS

FIG. 1 illustrates a front view of an example of a semiconductor molding apparatus.

FIGS. 2, 3, 4, and 5 illustrate plan views of examples of semiconductor molding apparatuses.

FIG. 6 illustrates a front view showing an example of a semiconductor molding apparatus.

FIG. 7 illustrates a front view showing a semiconductor molding apparatus.

FIGS. 8 and 9 illustrate front views of an example of a semiconductor molding apparatus over time.

FIG. 10 illustrates an enlarged front view showing a semiconductor molding apparatus of FIG. 9.

FIG. 11 illustrates a front view of the semiconductor molding apparatus from FIGS. 8 and 9 at a later time.

FIG. 12 illustrates an enlarged front view of the semiconductor molding apparatus of FIG. 11.

FIG. 13 illustrates a front view of an example of a semiconductor molding apparatus.

FIG. 14 illustrates a flow chart showing an example of a compression molding method.

### DETAILED DESCRIPTION

In the following, like reference numerals may indicate like components throughout the description.

In this description, symbol D1 may indicate a first direction, symbol D2 may indicate a second direction that intersects the first direction D1, and symbol D3 may indicate a third direction that intersects each of the first direction D1 and the second direction D2. The third direction D3 may be called an upward direction, and a direction opposite to the third direction D3 may be called a downward direction. In addition, each of the first and second directions D1 and D2 may be called a horizontal direction.

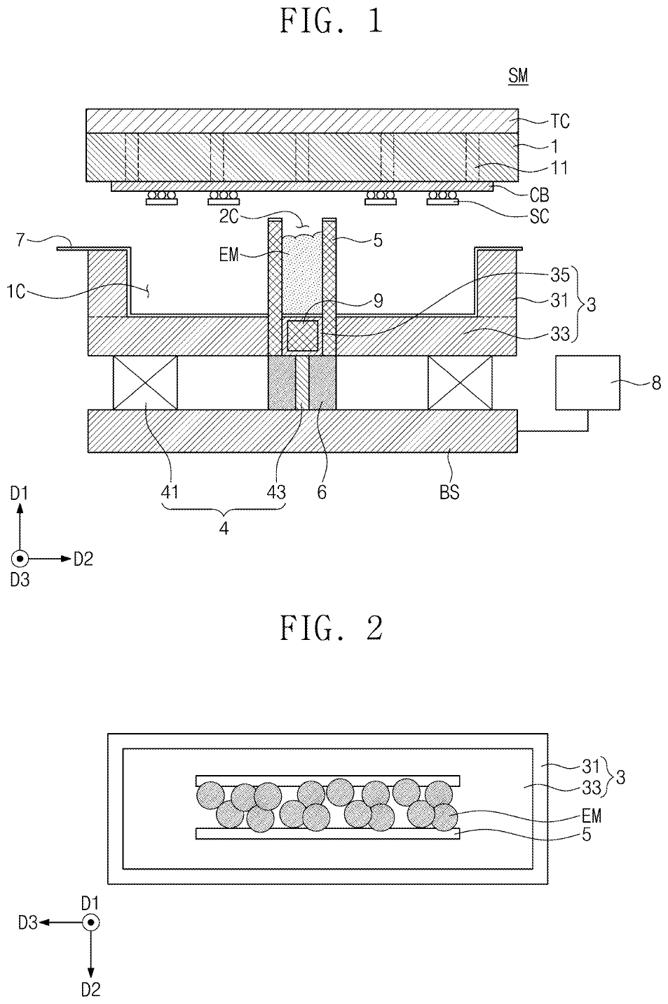

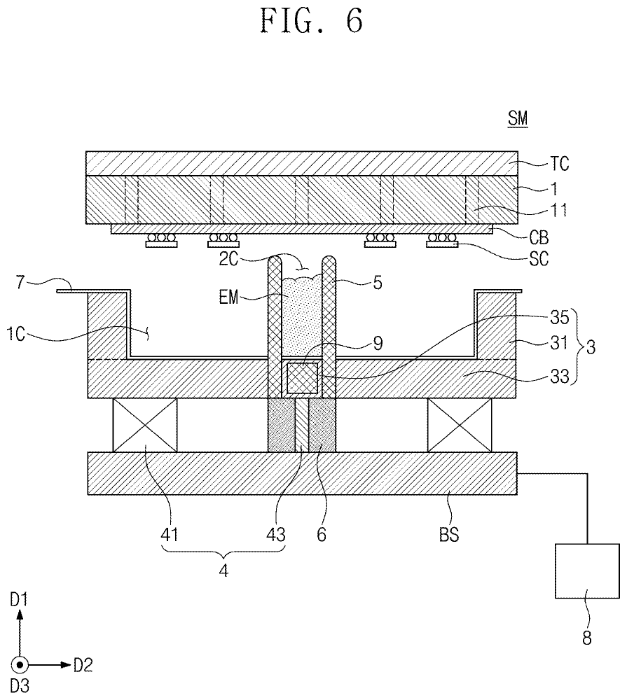

FIG. 1 illustrates a front view showing a semiconductor molding apparatus SM. FIGS. 2-5 illustrate plan views of examples of the semiconductor molding apparatuses SM. SM. FIG. 6 illustrates a front view showing an example of the semiconductor molding apparatus SM.

Referring to FIG. 1, the semiconductor molding apparatus SM is provided. The semiconductor molding apparatus SM includes an upper mold 1, a lower mold 3, a guide member 5, a guide lift 6, a lower mold lift 4, a heater 9, and a film 7.

The upper mold 1 may support a substrate CB. For example, the substrate CB may be supported on a bottom surface of the upper mold 1. The substrate CB may include a printed circuit board (PCB). The substrate CB may be supported under vacuum pressure on the bottom surface of the upper mold 1. The upper mold 1 may provide a vacuum hole 11 exposed on the bottom surface of the upper mold 1. The upper mold 1 may use a vacuum pump (not shown) to reduce pressure of the vacuum hole 11 to allow the upper mold 1 to fix the substrate CB. Alternatively, an electrostatic force may be employed to fix the substrate CB to the bottom surface of the upper mold 1. Alternatively, an adhesive may be used to adhere the substrate CB to the bottom surface of the upper mold 1. However, the contact mechanism between the substrate CB and the bottom surface of the upper mold 1 is not limited thereto, and any other suitable methods may be adopted. A semiconductor chip SC may be bonded to a bottom surface of the substrate CB. For example, the semiconductor chip SC may be physically bonded and electrically connected to the bottom surface of the substrate CB. An adhesive may be used to achieve the physical bonding between the substrate CB and the semiconductor chip SC. A flip-chip bonding or a wire bonding may be used to achieve the electrical connection between the substrate CB and the semiconductor chip SC. The physical and electrical connection between the substrate CB and the semiconductor chip SC are not limited thereto, and any other suitable methods may be adopted. A plurality of semiconductor chips SC may be connected to the bottom surface of the substrate CB. In this description, a single semiconductor chip SC will be discussed in the interest of convenience. The semiconductor chip SC may be a multi-chip having a structure in which at least two semiconductor devices are stacked. For example, the semiconductor chip SC may be a memory device where at least two semiconductor devices are of the same type. The semiconductor chip SC may have a structure in which one of at least two semiconductor devices is a memory device and another of at least two semiconductor devices is a micro-controller device. However, the structure of the semiconductor chip SC is not limited thereto.

The upper mold 1 may be combined with a thickness control unit TC. The thickness control unit TC may provide the upper mold 1 with pressure to control regional thickness or parallelism of a semiconductor molding region. The upper mold 1 may be divided into a plurality of segments (not shown). In this description, an entirety of the upper mold 1 will be treated as a single unitary piece. The upper mold 1 may be fixed. The present disclosure, however, is not limited thereto, and the upper mold 1 may move vertically or laterally. The upper mold 1 may approach the lower mold 3.

The lower mold 3 may provide a first cavity 1C capable of being filled with a resin EM. The first cavity 1C may have a certain depth to be filled with the resin EM. The resin EM may include a thermoplastic or thermosetting resin. The resin EM may include a granular resin, a powdered resin, a liquid resin, a plate-like resin, a sheet-like resin, a film-like resin, and a paste-like resin. The resin EM may include a transparent resin, a translucent resin, an opaque resin, or a combination thereof.

The first cavity 1C may have a cuboid shape. The present disclosure, however, is not limited thereto. The first cavity 1C may have a cylindrical shape, a cubic shape, or any other suitable shapes. The first cavity 1C may be a molding space.

During a molding process, the substrate CB and the semiconductor chip SC may be partially immersed by the resin EM filling the first cavity 1C. The lower mold lift 4 may drive the lower mold 3 to move vertically. The lower mold 3 may include a base plate 33 that extends in a horizontal direction, a sidewall member 31 that upwardly extends from the base plate 33, and a base pusher 35. When the first cavity 1C is filled with the resin EM, the base plate 33 may support the resin EM. A top surface of the base plate 33 may define the first cavity 1C. The base plate 33 may have a cuboid or cylindrical shape, but the present disclosure is not limited thereto. An inner lateral surface of the sidewall member 31 may define the first cavity 1C. One of the upper mold 1 and the lower mold 3 may move upwardly or downwardly to adjust a distance between the upper mold 1 and the lower mold 3. Alternatively, both of the upper mold 1 and the lower mold 3 may move. The distance between the upper mold 1 and the lower mold 3 may be adjusted to cause the resin EM to partially immerse the substrate CB and the semiconductor chip SC. The upper mold 1 and the lower mold 3 may be provided therebetween with a sealing member (not shown) such as an O-ring.

The lower mold 3 may include the base pusher 35. For example, from a plan view, the lower mold 3 may include the base pusher 35 positioned in a second cavity 2C. When viewed in plan view, the base pusher 35 may be positioned within the guide member 5. In this description, the phrase “when viewed in plan view” may mean “when viewed from above” as shown in FIG. 2. The base pusher 35 may be configured to vertically move independently of the sidewall member 31 and the base plate 33.

Referring to FIGS. 1 and 6, the lower mold 3 is combined with the heater 9 capable of applying heat to the first cavity 1C and the second cavity 2C. For example, the heater 9 may heat the resin EM present in the first cavity 1C and the second cavity 2C. The heater 9 may be positioned within the lower mold 3. When viewed in plan view, the heater 9 may be positioned in a space formed by the guide member 5. When viewed in plan view, the heater 9 may be positioned within the guide member 5. The present disclosure, however, is not limited thereto, and when viewed in plan view, the heater 9 may expand to cover an entirety of the base plate 33. The heater 9 may include a hot wire.

Referring still to FIGS. 1 and 6, the lower mold lift 4 includes a first lower mold lift 41 and a second lower mold lift 43. The first lower mold lift 41 may drive the base plate 33 and the sidewall member 31 to move vertically. The second lower mold lift 43 may drive the base pusher 35 to move vertically. For example, the second lower mold lift 43 may be configured such that the base pusher 35 may vertically move at a speed different from that of the base plate 33 and the sidewall member 31. The lower mold lift 4 may include one or more of a resilient member, a motor, and a piston. The present disclosure, however, is not limited thereto, and the lower mold lift 4 may further include other members capable of driving the lower mold 3 to move vertically. The resilient member may include, for example, a spring or a rubber bar. The spring may include one or more of high-carbon steel wire rods (HSWR), piano wires (PWR), oil tempered wires, stainless steel wires (STS), brass, phosphor bronze, nickel silver (Cu—Ni—Zn), beryllium bronze, titanium bronze, titanium alloy, cobalt alloy, and nickel alloy. However, the resilient member is not limited to that mentioned above, and may include any other suitable materials that have a tendency to return to its original state when an external force is applied. The lower mold lift 4 may include both of a resilient member and a motor. The resilient member may provide the lower mold 3 with power generated from the motor. The resilient member may prevent an abrupt increase or reduction in pressure applied to the resin EM. The resilient member may effectively transfer the power generated from the motor to the lower mold 3.

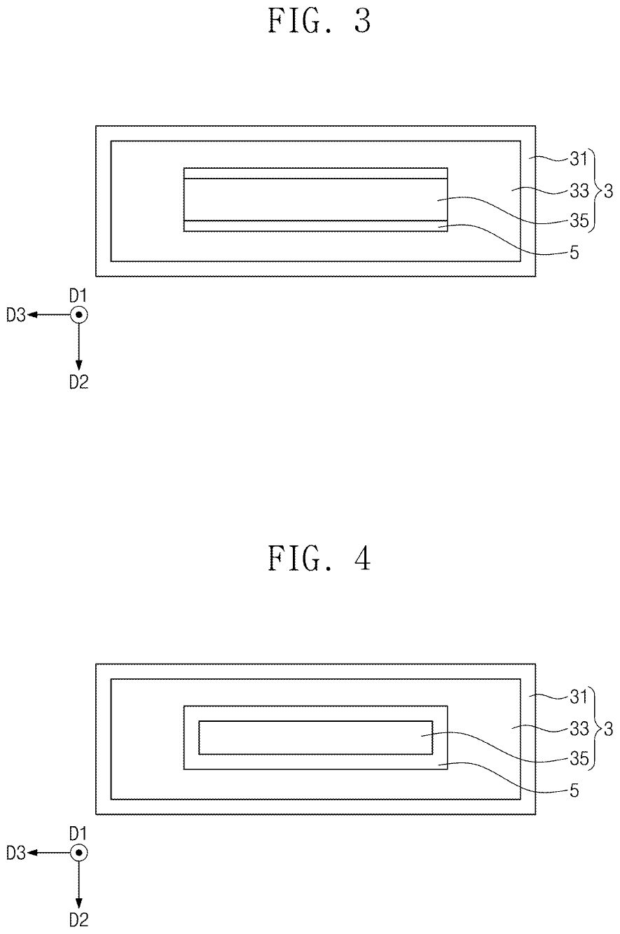

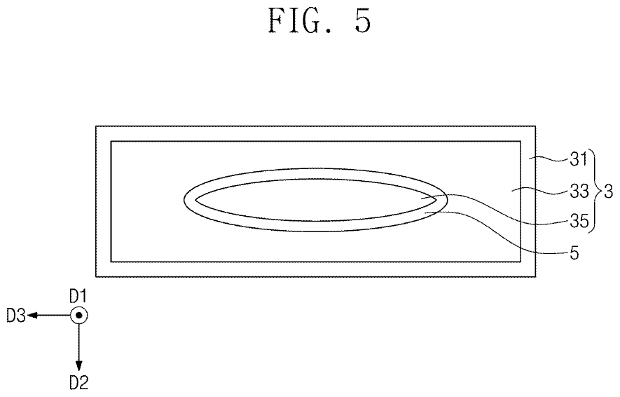

Referring to FIGS. 1 and 2, the guide member 5 provides the second cavity 2C to store the resin EM. The second cavity 2C may have a certain depth capable of storing the resin EM. A volume of the second cavity 2C may decrease when the guide member 5 moves downwardly. The guide member 5 may vertically penetrate the lower mold 3. The guide member 5 may be combined with the lower mold 3, e.g., components of the guide member 5 can interlock with components of the lower mold 3. The guide member 5 may be combined with guide lift 6. The guide lift 6 may include one or more of a resilient member, a motor, and a piston. The present disclosure, however, is not limited thereto, and the guide lift 6 may further include other members capable of driving the guide member 5 to move vertically. The resilient member may include a spring or a rubber bar. The spring may include one or more of high-carbon steel wire rods (HSWR), piano wires (PWR), oil tempered wires, stainless steel wires (STS), brass, phosphor bronze, nickel silver (Cu—Ni—Zn), beryllium bronze, titanium bronze, titanium alloy, cobalt alloy, and nickel alloy. However, the resilient member is not limited to that mentioned above, and may include any other suitable materials that have a tendency to return to its original state when an external force is applied. The guide lift 6 may drive the guide member 5 to move vertically. For example, the guide lift 6 may drive a top surface of the guide member 5 to move between the top surface of the base plate 33 and a top surface of the sidewall member 31. However, a moving range of the top surface of the guide member 5 is not limited thereto. The top surface of the guide member 5 may be located at a level higher than that of a top surface of the sidewall member 31. When viewed in plan view, the guide member 5 may be shaped like a pair of parallel lines, an ellipse, or a rectangle. However, the shape of the guide member 5 is not limited to the example above, and may have any other suitable shapes. Referring to FIG. 3, when the guide member 5 has an open shape, the base pusher 35 may be positioned in a space surrounded by the guide member 5, in a plan view. Referring to FIGS. 4 and 5, when the guide member 5 has a closed shape, the base pusher 35 may be positioned within the guide member 5, in a plan view. Referring to FIG. 6, the guide member 5 may have a curved surface at an upper portion thereof. For example, the upper portion of the guide member 5 may have a rounded shape.

The guide lift 6 and the lower mold lift 4 may be supported by a fixing support BS. The fixing support BS may further include other configurations for molding. The lower mold lift 4 may be driven by power from the fixing support BS. The guide lift 6 may be driven by power from the fixing support BS. However, other relationships between the fixing support BS and the guide lift 6 and between the fixing support BS and the lower mold lift 4 are possible.

The film 7 may coat the top surface of the sidewall member 31, the inner lateral surface of the sidewall member 31, and the top surface of the base plate 33. The film 7 may not allow the resin EM to contaminate the lower mold 3. For easy separation between the resin EM and the lower mold 3 after molding, the lower mold 3 may be covered with the film 7 before supply of the resin EM. The film 7 may be fixed by vacuum pressure to the lower mold 3. For example, a vacuum pump (not shown) may be used to reduce pressure of a pore between the film 7 and each of the sidewall member 31 and the base plate 33, and the film 7 may be fixed onto one surface of the lower mold 3. Although not shown, left and right sides of the film 7 may be correspondingly wounded around winding rollers. The winding rollers may rotate to laterally move the film 7. Therefore, when a new molding process is performed, the winding roller may rotate to allow the lower mold 3 to receive a portion of the film 7 that is not used in a molding process.

Referring to FIGS. 1 and 6, the semiconductor molding apparatus SM further includes a controller 8. The controller 8 may include a temperature controller and an operation controller. The operation controller may control the lower mold lift 4. For example, the operation controller may determine elevation sequences, elevation heights, and elevation speeds of the first lower mold lift 41 and the second lower mold lift 43. The temperature controller may control the heater 9, such a hot wire, to adjust an amount of heat applied to the resin EM and a resin heating time.

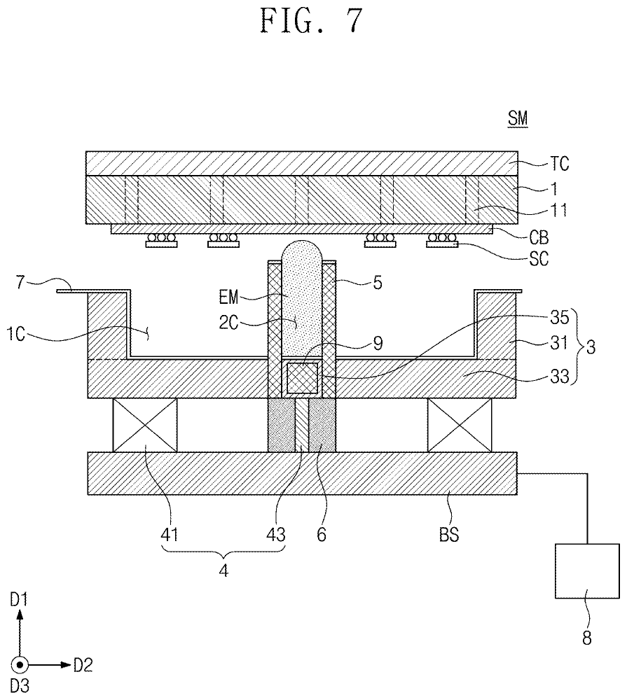

FIG. 7 illustrates a front view showing the semiconductor molding apparatus SM.

Referring to FIG. 7, the semiconductor molding apparatus SM is provided which stores the resin EM heated by the heater 9. The heater 9 may preheat the lower mold 3. The heater 9 may apply heat to the second cavity 2C. For example, the heater 9 may preheat the lower mold 3 to a temperature of about 80° C. to about 130° C. The heater 9 may heat the lower mold 3 to a melting temperature of about 160° C. to about 180° C. For example, in a state where the lower mold 3 is preheated, the heater 9 may heat the resin EM introduced into the second cavity 2C to a melting temperature of the resin EM. The heater 9 may preheat the lower mold 3 where the resin EM is introduced into the second cavity 2C, and then may heat the resin EM to its melting temperature. The temperatures mentioned above may be changed based on a kind of the resin EM. When the resin EM is heated by the heater 9, the heater 9 may have an increased volume. When the resin EM is heated by the heater 9, the resin EM may be expanded. When the resin EM has an increased volume, the guide member 5 may cause the resin EM to rise upwardly. The resin EM may rise until contact of the substrate CB with the substrate CB.

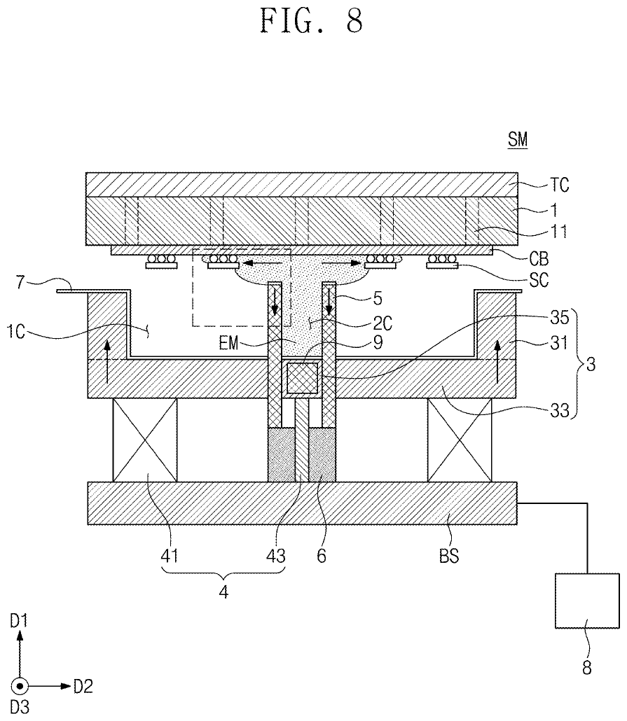

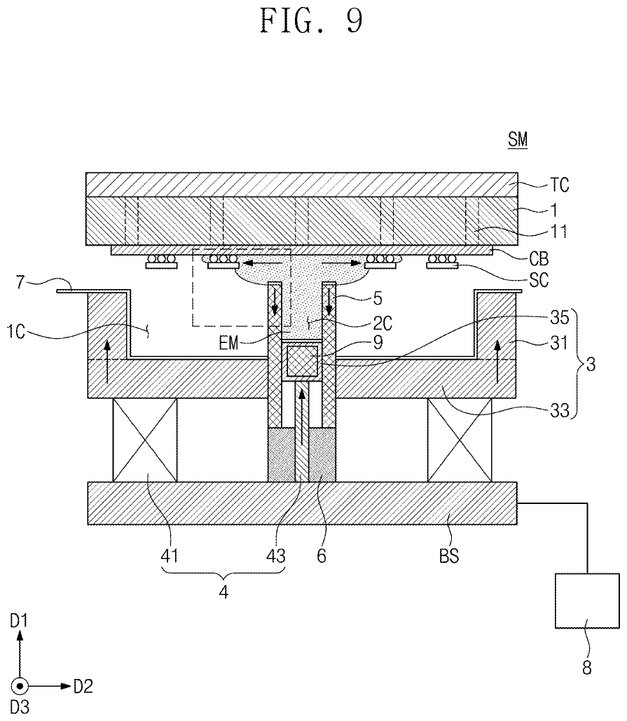

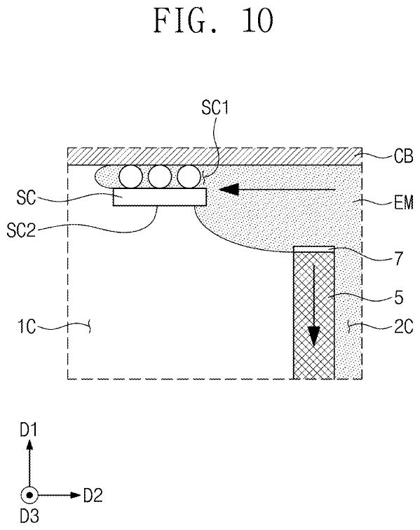

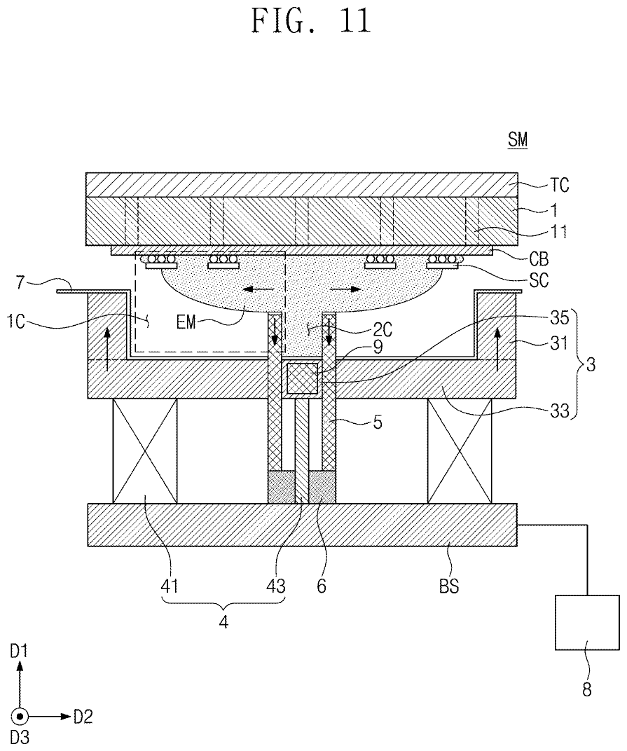

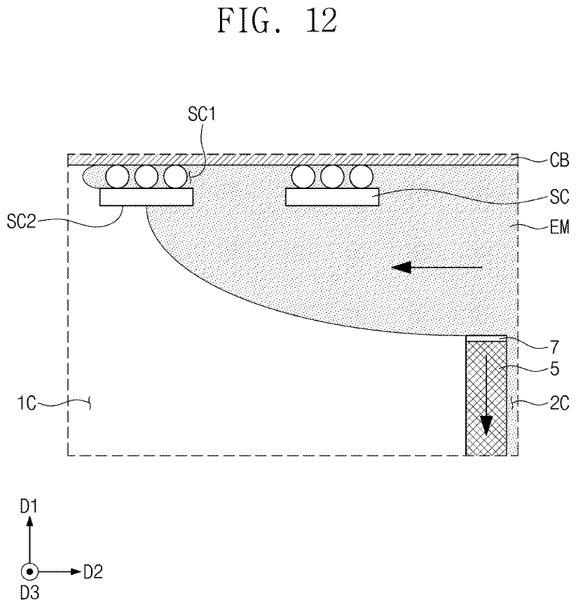

FIG. 8 illustrates a front view showing the semiconductor molding apparatus SM. FIG. 9 illustrates a front view showing the semiconductor molding apparatus SM. FIG. 10 illustrates an enlarged front view showing the semiconductor molding apparatus SM. FIG. 11 illustrates a front view showing the semiconductor molding apparatus SM. FIG. 12 illustrates an enlarged front view showing the semiconductor molding apparatus SM.

Referring to FIGS. 8, 9, and 11, the first lower mold lift 41 and the second lower mold lift 43 move upwardly. The ascent of the first lower mold lift 41 and the second lower mold lift 43 may cause an ascent of the sidewall member 31 and the base plate 33. Referring to FIG. 9, the first lower mold lift 41 and the second lower mold lift 43 move upwardly at different elevation speeds from each other. The second lower mold lift 43 may move upwardly at an elevation speed greater than that of the first lower mold lift 41. Alternatively, the speed of the second lower mold lift 43 may be the same as that of the first lower mold lift 41. The base pusher 35 may support the resin EM. As the second lower mold lift 43 moves upwardly at a high speed, the base pusher 35 may also move upwardly at a high speed. The base pusher 35 may move upwardly at a higher speed than that of the base plate 33 and the sidewall member 31. The ascent of the base pusher 35 may upwardly raise the resin EM that is melted.

Referring to FIGS. 8, 9, and 11, the guide lift 6 drives the guide member 5 to move downwardly. A top surface of the guide member 5 may not be in contact with the substrate CB. The guide member 5 may guide the inflated resin EM to contact the bottom surface of the substrate CB. After the resin EM contacts the bottom surface of the substrate CB, the resin EM may fill the first cavity 1C while the guide member 5 gradually moves downwardly. When the base plate 33, the sidewall member 31, and the base pusher 35 move upwardly, the guide member 5 may move downwardly to cause the resin EM to effectively fill the first cavity 1C.

Referring to FIGS. 10 and 12, the guide member 5 causes the resin EM to rise and contact the bottom surface of the substrate CB. A joint-gap SCI may be defined to refer to a space between the semiconductor chip SC and the substrate CB. A chip-top surface SC2 may be defined to refer to a top surface of the semiconductor chip SC or a surface of the semiconductor chip SC opposite to the lower mold 3. The guide member 5 may cause the resin EM to first fill the joint-gap SC1. As the guide member 5 moves downwardly, the resin EM may also fill a space between the chip-top surface SC2 and the base plate 33.

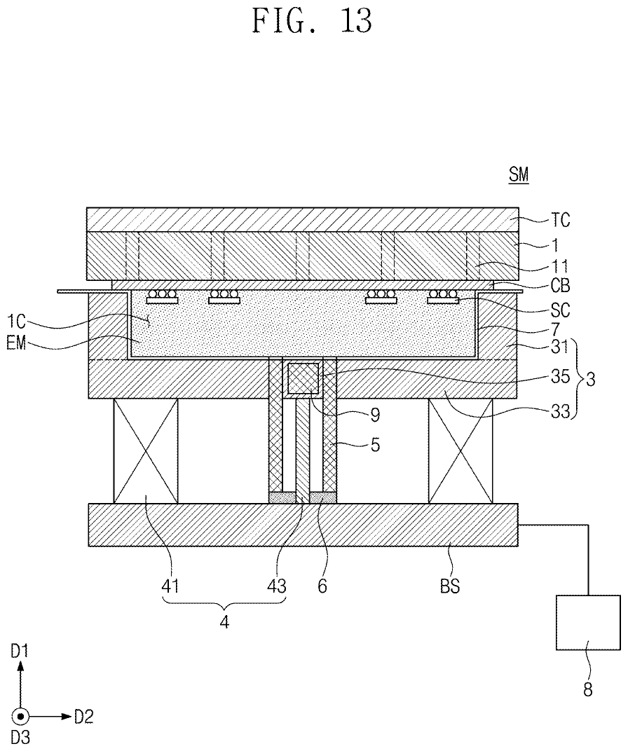

FIG. 13 illustrates a front view showing the semiconductor molding apparatus SM.

Referring to FIG. 13, the lower mold 3 contacts the upper mold 1. The lower mold 3 may contact the substrate CB supported on the bottom surface of the upper mold 1. When the lower mold 3 is coated with the film 7, the film 7 and the substrate CB may contact each other. When the lower mold 3 is coated with the film 7, the film 7 and the bottom surface of the upper mold 1 may contact each other. The resin EM may be cured with a compressive force exerted when the upper mold 1 and the lower mold 3 are engaged with each other. The resin EM may be cured for about 50 seconds to about 90 seconds. However, the curing time of the resin EM is not limited thereto and may be changed based on a kind of the resin EM. The lower mold 3 and the upper mold 1 may approach each other to close the first cavity 1C. The descent of the guide member 5 may reduce a volume of the second cavity 2C. When the first cavity 1C is closed, the guide member 5 may be positioned below the first cavity 1C. When the guide member 5 is positioned below the first cavity 1C, the second cavity 2C may disappear. When the first cavity 1C is closed, the first cavity 1C may be filled with the resin EM. For example, when the first cavity 1C is closed, the first cavity 1C and the resin EM may have the same volume.

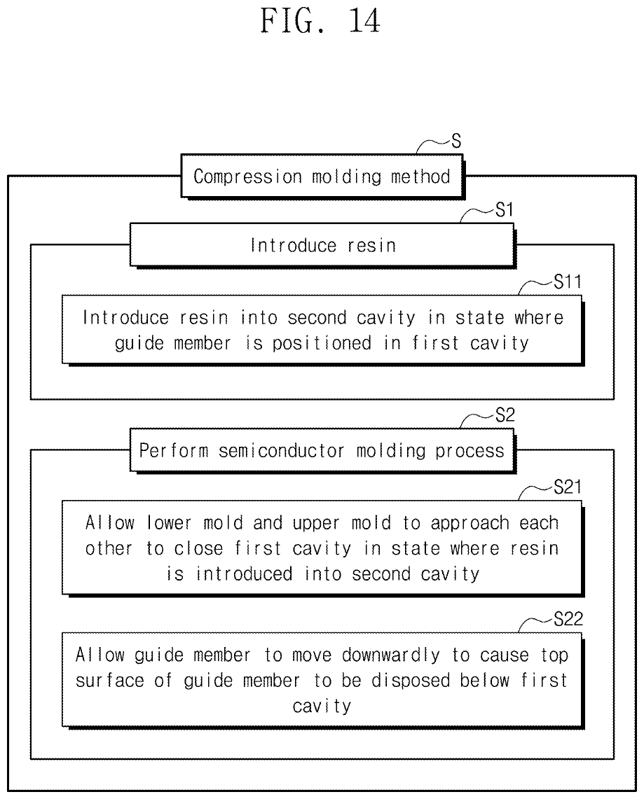

FIG. 14 illustrates a flow chart showing a compression molding method.

Referring to FIG. 14, a compression molding C includes introducing the resin EM (S1) and performing a semiconductor molding process (S2).

The resin introduction step S1 may include introducing the resin EM into the second cavity 2C in a state where the guide member 5 is positioned in the first cavity 1C (S11). When the resin EM is introduced, the second cavity 2C may be positioned in the first cavity 1C. For example, when the resin EM is introduced, the top surface of the guide member 5 may not be positioned below the first cavity 1C. When the resin EM is introduced, the top surface of the guide member 5 may be located at a level higher than that of the top surface of the base plate 33. The introduction of the resin EM into the second cavity 2C may be performed simultaneously with a step of fixing the substrate CB to the upper mold 1. The introduction of the resin EM into the second cavity 2C may be performed separately from the step of fixing the substrate CB to the upper mold 1.

The semiconductor molding step S2 may include allowing the lower mold 3 and the upper mold 1 to approach each other to close the first cavity 1C in a state where the resin EM is introduced into the second cavity 2C (S21) and allowing the guide member 5 to move downwardly to cause the top surface of the guide member 5 to be disposed below the first cavity 1C (S22). The cavity closing step S21 may include allowing the base pusher 35 to move upwardly at a speed greater than that of the base plate 33 and the sidewall member 31. The compression molding method S may further include, prior to the semiconductor molding step S2, allowing the heater 9 to preheat an inside of the second cavity 2C.

The cavity closing step S21 may be performed by the lower mold lift 4. The controller 8 may control an elevation speed of the lower mold lift 4 to close the first cavity 1C. The elevation speed of the lower mold lift 4 may be controlled by the controller 8 such that the first cavity 1C may not be closed at an excessive pressure. For accomplishment of effective molding, the controller 8 may independently control the speed of the second lower mold lift 43 and the speed of the first lower mold lift 41. The descent step S22 may be performed by the guide lift 6. The controller 8 may control a speed of the guide lift 6. When the lower mold 3 moves upwardly, the controller 8 may control the guide lift 6 not to allow the top surface of the guide member 5 to contact the upper mold 1. When the lower mold 3 moves upwardly, the controller 8 may control the guide lift 6 not to allow the top surface of the guide member 5 to contact the bottom surface of the substrate CB.

In some implementations, as a resin fills a joint-gap SC1 and then contacts a chip-top surface SC2, it is possible to reduce a difference in speed of resin movement between the joint-gap SC1 and the chip-top surface SC2. In some implementations, the occurrence of void is decreased due to the reduction in speed difference of resin movement between the joint-gap SC1 and the chip-top surface SC2.

In some implementations, as a guide lift 6 is positioned at a center of a first cavity 1C, there is a reduction in length of a resin movement path. In some implementations, a reduction in length of a resin movement path causes a decrease in occurrence of void.

In some implementations, a resin EM amount suitable to a product thickness is supplied to reduce waste of resin EM.

In some implementations, movement speeds of a guide lift 6 and a lower mold lift 4 are controlled to adjust a flow rate of resin EM.

In some implementations, it is possible to increase flowability of resin EM in a joint-gap SC1.

In some implementations, it is possible to reduce flow asymmetry of resin EM between a joint-gap SC1 and a chip-top SC2.

In some implementations, it is possible to reduce the occurrence of void in a molding procedure.

In some implementations, it is possible to decrease a flow length of resin EM.

Effects of the present disclosure is not limited to the mentioned above, other effects which have not been mentioned above will be clearly understood to those skilled in the art from the following description.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations and even initially be claimed as such, one or more features from a combination can in some cases be excised from the combination, and the combination may be directed to a subcombination or variation of a subcombination.

Although the present inventive concepts have been described in connection with some embodiments of the present inventive concepts illustrated in the accompanying drawings, it will be understood to those skilled in the art that various changes and modifications may be made without departing from the technical spirit and essential feature of the present inventive concepts. It therefore will be understood that the embodiments described above are just illustrative but not limitative in all aspects.

What is claimed is:

1. A semiconductor molding apparatus, comprising:
an upper mold capable of supporting a substrate;
a lower mold that provides a first cavity;
a guide member that provides a second cavity and that vertically penetrates the lower mold; and
a guide lift configured to vertically drive the guide member,
wherein the lower mold comprises:
a base plate that extends in a horizontal direction; and
a sidewall member that upwardly extends from the base plate,
wherein the guide lift is configured to vertically drive the guide member such that a top surface of the guide member moves between a top surface of the base plate and a top surface of the sidewall member.

2. The apparatus of claim 1, further comprising a heater configured to apply heat to the second cavity and positioned within the lower mold.

3. The apparatus of claim 1, wherein, when viewed in plan view, the guide member is shaped as a pair of parallel lines, an ellipse, or a rectangle.

4. The apparatus of claim 1, wherein the guide lift comprises at least one of a resilient member and a motor.

5. The apparatus of claim 1, further comprising a first lower mold lift configured to vertically drive the lower mold.

6. The apparatus of claim 5, wherein the first lower mold lift comprises at least one of a resilient member and a motor.

7. The apparatus of claim 1, wherein
the lower mold further comprises a base pusher in the second cavity when viewed in plan view, and
the apparatus further comprises a second lower mold lift configured to vertically drive the base pusher, wherein motion of the base pusher is independent of motion of the sidewall member and motion of the base plate.

8. The apparatus of claim 1, further comprising a film coating the top surface of the sidewall member, an inner lateral surface of the sidewall member, and the top surface of the base plate.

9. The apparatus of claim 1, wherein an upper portion of the guide member has a curved surface.

10. A semiconductor molding apparatus, comprising:
an upper mold supporting a substrate;
a lower mold providing a first cavity;
a guide member providing a second cavity and configured to interlock with the lower mold; and
a guide lift configured to vertically drive the guide member,
wherein the lower mold comprises:
a base plate having a top surface defining the first cavity; and
a sidewall member upwardly extending from the base plate and having an inner lateral surface defining the first cavity,
wherein the guide lift is configured to allow motion of a top surface of the guide member between the top surface of the base plate and a top surface of the sidewall member.

11. The apparatus of claim 10, wherein the guide lift comprises at least one of a resilient member and a motor.

12. The apparatus of claim 10, wherein the lower mold further comprises a base pusher configured to vertically move independently of the base plate and the sidewall member.

13. The apparatus of claim 12, further comprising:
a first lower mold lift configured to vertically drive the base plate and the sidewall member; and
a second lower mold lift configured to vertically drive the base pusher, wherein motion of the base pusher is independent of motion of the sidewall member and motion of the base plate.

14. The apparatus of claim 10, wherein, when viewed in plan view, the guide member is shaped as two parallel lines, an ellipse, or a rectangle.

15. A compression molding method, comprising:
introducing a resin into a semiconductor molding apparatus; and
performing a semiconductor molding process,
wherein the semiconductor molding apparatus comprises:
an upper mold supporting a substrate;
a lower mold providing a first cavity;
a lower mold lift configured to vertically drive the lower mold; and
a guide member providing a second cavity configured to store the resin when the resin is introduced into the semiconductor molding apparatus, the guide member vertically penetrating the lower mold,
wherein introducing the resin into the semiconductor molding apparatus comprises introducing the resin to the second cavity in a state where the guide member is positioned in the first cavity,
wherein performing the semiconductor molding process comprises:
moving the lower mold and the upper mold toward each other to close the first cavity in a state where the resin is introduced into the second cavity; and
downwardly moving the guide member to cause a top surface of the guide member to be disposed below the first cavity.

16. The method of claim 15, wherein the semiconductor molding apparatus further comprises a heater configured to apply heat to the second cavity.

17. The method of claim 16, further comprising, before performing the semiconductor molding process, preheating, by the heater, an inside of the second cavity.

18. The method of claim 15, wherein the lower mold comprises:
a base plate having a top surface supporting the resin;
a sidewall member upwardly extending from the base plate; and
a base pusher within the guide member when viewed in plan view, and
wherein the lower mold lift comprises:
a first lower mold lift configured to vertically drive the sidewall member and the base plate; and
a second lower mold lift configured to vertically drive the base pusher.

19. The method of claim 18, wherein moving the lower mold and the upper mold toward each other to close the first cavity comprises upwardly moving the base pusher at a speed greater than a speed of the base plate and of the sidewall member.

20. The method of claim 15, wherein, when viewed in plan view, the guide member is shaped as a pair of parallel lines, a rectangle, or an ellipse.
